(19) United States
(12) Patent Application Publication
(10) Pub. No.: US 2021/0211564 A1
(43) Pub. Date: Jul. 8, 2021

(54) DISPLAY PANEL, DRIVING METHOD AND MANUFACTURING METHOD THEREOF, AND DISPLAY APPARATUS

(71) Applicants: BOE TECHNOLOGY GROUP CO., LTD., Beijing (CN); BEIJING BOE DISPLAY TECHNOLOGY CO., LTD., Beijing (CN)

(72) Inventors: Sha LIU, Beijing (CN); Yijie HUO, Beijing (CN); Yun QIU, Beijing (CN); Xiang FENG, Beijing (CN); Qiang ZHANG, Beijing (CN); Xiao SUN, Beijing (CN); Zhaokun YANG, Beijing (CN); Ruizhi YANG, Beijing (CN)

(73) Assignees: BOE Technology Group Co., Ltd., Beijing (CN); Beijing BOE Display Technology Co., Ltd., Beijing (CN)

(21) Appl. No.: 15/778,248

(22) PCT Filed: Dec. 7, 2017
(86) PCT No.: PCT/CN2017/115084

§ 371 Date: May 23, 2018

(30) Foreign Application Priority Data
Mar. 31, 2017 (CN) 201710212192.6

(51) Int. Cl. H04N 5/225; G09G 3/20; H01L 31/113; G02F 1/133; G02F 1/1335; G02F 1/1362

(52) U.S. Cl. CPC H04N 5/2257; G09G 3/20; H01L 31/1136; G02F 1/13318; G09G 2300/0439; G02F 1/136222; G02F 1/136286; G09G 2300/0426; G02F 1/133526

(57) ABSTRACT

A display panel includes a plurality of sub-pixels, and an image capturing assembly including a plurality of photoelectric converters and an image integrator electrically coupled to each photoelectric converter. At least one sub-pixel contains one photoelectric converter. Each photoelectric converter can convert an optical signal from an outside light reaching thereonto into an electrical signal. The image integrator can receive the electrical signal from each photoelectric converter to thereby build an image based thereupon. The display panel further includes a substrate, and a color filter layer disposed over the substrate and including a plurality of color blocks, each of a primary color and corresponding to one sub-pixel. The photoelectric converters are each disposed between the substrate and the color filter layer. Each photoelectric converter can convert an optical signal from an outside light entering through one of the plurality of color blocks into an electrical signal.

### CROSS-REFERENCE TO RELATED APPLICATION

The present application claims priority to Chinese Patent Application No. 201710212192.6 filed on Mar. 31, 2017, the disclosure of which is hereby incorporated by reference in its entirety.

### TECHNICAL FIELD

The present disclosure relates generally to a field of display technologies, and specifically to a display panel and its driving method and manufacturing method, and a display apparatus.

### BACKGROUND

Thin-film transistor liquid crystal displays (TFT-LCDs) have advantages such as small volume, low power consumption, and non-radiation, etc. In recent years, they have been rapidly and widely utilized in the industry, and have occupied a dominant position in the flat panel display market.

Along with the constant development of display technologies, liquid crystal display (LCD) devices need to have multiple functionalities in order to satisfy the demands of the users to thereby improve their market competitiveness.

### SUMMARY

In a first aspect, the present disclosure provides a display panel. The display panel comprises a plurality of sub-pixels and an image capturing assembly. The image capturing assembly comprises a plurality of photoelectric converters and an image integrator that is electrically coupled to each of the plurality of photoelectric converters.

In the display panel, at least one of the plurality of sub-pixels is configured to contain one of the plurality of photoelectric converters to thereby each form a first sub-pixel. Each of the plurality of photoelectric converters is configured to convert an optical signal from an outside light reaching thereonto into an electrical signal. The image integrator is configured to receive the electrical signal from the each of the plurality of photoelectric converters to thereby build an image based thereupon.

The display panel further includes an array substrate and a color filter layer. The array substrate comprises a substrate, and the color filter layer is disposed over the substrate and comprises a plurality of color blocks. Each of the plurality of color blocks is of a primary color and corresponds to one of the plurality of sub-pixels. The plurality of photoelectric converters are each disposed between the substrate and the color filter layer. Each of the plurality of photoelectric converters is configured to convert an optical signal from an outside light entering through one of the plurality of color blocks into an electrical signal.

The display panel can further comprise an optical functional layer, which is disposed over a surface of the color filter layer that is opposing to the substrate. The optical functional layer is arranged such that an orthographic projection thereof on the substrate covers an orthographic projection of each first sub-pixel on the substrate, and is configured to increase a quantity of the light reaching one of the plurality of photoelectric converters in the each first sub-pixel.

Herein the optical functional layer can include a plurality of first-level microlenses, which are arranged in a matrix, and each of the plurality of first-level microlenses is configured to have a surface that is convex in a direction away from the substrate.

The optical functional layer of the optical functional layer can further include a plurality of second-level microlenses which are disposed over a surface of the plurality of first-level microlenses opposing to the substrate, and each of the plurality of second-level microlenses has a surface that is convex in a direction away from the substrate.

It is possible that the optical functional layer can further include a plurality of third-level microlenses, fourth-level microlenses, which can be arranged in a similar manner over the plurality of second-level microlenses, and have a similar structure as the plurality of second level microlenses.

The display panel may further include a plurality of read lines, a plurality of scan lines, and a plurality of common electrode lines. Each of the plurality of photoelectric converters is electrically coupled to one of the plurality of read lines, one of the plurality of scan lines, and one of the plurality of common electrode lines, and is configured to convert the optical signal into the electrical signal under control of the one of the plurality of scan lines and the one of the plurality of common electrode lines, and then to output the electric signal to the one of the plurality of read lines. The image integrator is electrically coupled to each of the plurality of read lines, and is configured to receive the electric signal transmitted through the each of the plurality of read lines.

In the display panel as described above, each of the plurality of read lines can also serve as a data line; and each of the plurality of scan lines can also serve as a gate line.

The display panel can further include a driving circuit, a source electrode driver, and a gate electrode driver. The image integrator is further configured to integrate the electrical signal from the each of the plurality of photoelectric converters into an image data based on a location of a first sub-pixel corresponding thereto and a color block corresponding thereto. The driving circuit is electrically coupled to the source electrode driver, the image integrator and the gate electrode driver, and is configured to receive the image data outputted from the image integrator, and then to output control signals to the source electrode driver and the gate electrode driver to thereby display an image based on the image data.

In the display panel, each of the plurality of photoelectric converters may comprise a phototransistor and a commutation diode. It is configured such that a gate electrode of the phototransistor is electrically coupled to one of the plurality of scan lines, a first electrode of the phototransistor is electrically coupled to one of the plurality of read lines, a second electrode of the phototransistor is electrically coupled to an anode of the commutation diode, and a cathode of the commutation diode is electrically coupled to one of the plurality of common electrode lines.

In the display panel, the image integrator may include an electron-to-voltage converter, an amplifier, an analog-to-digital converter, a data processor, and a plurality of shift registers. Each of the plurality of shift registers is arranged within a first sub-pixel, is electrically coupled to one photoelectric converter corresponding to the first sub-pixel, and is configured to cache the electrical signal from the one photoelectric converter. The electron-to-voltage converter is electrically coupled to each of the plurality of shift registers, and is configured to convert the electrical signal cached therein into a voltage signal in a line-by-line manner. The amplifier is electrically coupled to the electron-to-voltage converter, and is configured to amplify the voltage signal from the electron-to-voltage converter to thereby obtain an amplified voltage signal. The analog-to-digital converter is electrically coupled to the amplifier, and is configured to convert the amplified voltage signal from the amplifier from an analog format into a digital signal. The data processor is electrically coupled to the analog-to-digital converter, and is configured to integrate the digital signal received from the analog-to-digital converter, and to form a planar dot array based on a location of each first sub-pixel and each color block corresponding to the each first sub-pixel to thereby generate the image data.

In the display panel, each of the plurality of sub-pixels can include a switch transistor, and each of the plurality of photoelectric converters can include a phototransistor. The switch transistor and the phototransistor are configured to share at least one film layer.

According to some embodiments, each first sub-pixel contains one switch transistor and one phototransistor.

According to some embodiments, the phototransistor comprises a first active layer, a source electrode and a drain electrode, a first insulating layer, a gate electrode, an optical-electrical conversion layer, a second insulating layer, and two signal lead lines.

The first active layer is disposed over the substrate; the source electrode and the drain electrode are disposed over the substrate and are arranged to juxtapose the first active layer; the first insulating layer is arranged to cover, and is configured to provide insulation to, the first active layer, the source electrode and the drain electrode; the gate electrode is disposed over the first insulating layer; the optical-electrical conversion layer is disposed over the gate electrode; the second insulating layer is arranged to cover, and is configured to provide insulation to, the gate electrode and the optical-electrical conversion layer; and the two signal lead lines are respectively coupled electrically to the source electrode through a first via arranged through the second insulating layer and the first insulating layer, and to the drain electrode through a second via arranged through the second insulating layer and the first insulating layer.

According to some embodiments, at least one of the source electrode and the drain electrode, the first insulating layer, the gate electrode, the second insulating layer, or any of the two signal lead lines of the phototransistor has a substantially same composition of, and is at a substantially same layer as, a film layer of the switch transistor.

Furthermore according to some embodiments, the source electrode and the drain electrode of the phototransistor have a substantially same composition of, and are at a substantially same layer as, a gate electrode of the switch transistor; the first insulating layer of the phototransistor has a substantially same composition of, and is at a substantially same layer as, a first insulating layer of the switch transistor; the gate electrode of the phototransistor has a substantially same composition of, and is at a substantially same layer as, a source electrode and a drain electrode of the switch transistor; the second insulating layer of the phototransistor has a substantially same composition of, and is at a substantially same layer as, a second insulating layer of the switch transistor; and the two signal lead lines of the phototransistor have a substantially same composition of, and are at a substantially same layer as, a pixel electrode of the switch transistor.

Furthermore, the second insulating layer of the switch transistor can be provided with a third via, wherein the pixel electrode of the switch transistor is electrically coupled to the drain electrode of the switch transistor through the third via.

In any one embodiment of the display panel as described above, the display panel can further include an encasing substrate, wherein the color filter layer is disposed over a surface of the encasing substrate that is opposing to the substrate.

The color filter layer can be disposed in the array substrate according to some other embodiments.

In the display panel, each first sub-pixel can be in an image capturing sub-region arranged in a non-display region of the display panel. Herein the image capturing sub-region can be arranged close to a peripheral region of the display panel.

In the display panel, each first sub-pixel can be in a display region of the display panel.

According to some embodiments, each first sub-pixel can be in a dummy display sub-region of the display region that is covered by a bezel disposed over a side thereof opposing to the substrate, and the bezel can be provided with a light-transmitting hole, arranged to allow a light from an environment of the display panel to transmit therethrough and reach a photoelectric converter corresponding to the each first sub-pixel.

According to some other embodiments, each first sub-pixel can be uniformly distributed at the display region.

In a second aspect, the disclosure further provides a display apparatus, which comprises a display panel according to any one of the embodiments as described above.

### BRIEF DESCRIPTION OF DRAWINGS

To more clearly illustrate some of the embodiments, the following is a brief description of the drawings. The drawings in the following descriptions are only illustrative of some embodiments. For those of ordinary skill in the art, other drawings of other embodiments can become apparent based on these drawings.

FIG. 1A is a structural diagram of a display panel according to one embodiment of the present disclosure;

FIG. 1B is a structural diagram of another display panel according to another embodiment of the present disclosure;

FIG. 2 is a top view of the display panel as shown in FIG. 1A or FIG. 1B;

FIG. 3A and FIG. 3B are respectively a photographic view and a diagram of the one level of microlenses in the optical function layer in the display panel as shown in FIG. 1A;

FIG. 3C, FIG. 3D, and FIG. 3E are diagrams illustrating the display panel during manufacturing of the optical function layer shown in FIG. 1A or FIG. 1B through coining process;

FIG. 3F illustrates a structural diagram of a first-level microlens and a plurality of second-level microlenses arranged on the surface of the first-level microlens in the optical function layer in the display panel as shown in FIG. 1B;

FIGS. 4A, 4B and 4C are respectively diagrams illustrating three configurations of the first sub-pixels in the display panel according to some embodiments of the disclosure;

FIG. 5A illustrates a specific configuration of the photoelectric converters in the display panel according to some embodiments of the disclosure;

FIGS. 5B and 5C are respectively the diagrams illustrating two types of corresponding relationship between the photoelectric converters and the first sub-pixels according to two embodiments of the disclosure;

FIGS. 6A-6D are diagrams illustrating the output process of the image integrator as shown in FIG. 2;

FIG. 7 is a flow chart illustrating a method for driving a display panel according to some embodiments of the disclosure;

FIG. 8 is a flow chart illustrating the different stages within one image frame in which images are displayed and captured in the method for driving a display panel according to embodiments of the present disclosure;

FIG. 9 illustrates the division of different stages within one image frame in the method for driving a display panel as shown in FIG. 8;

FIG. 10A is a structural diagram of one of the phototransistors M1 that are formed through the method for manufacturing a display panel as shown in FIG. 10;

FIG. 10B is a structural diagram of one of the switch transistors M2 that are formed at the same time as the phototransistors M1 as illustrated in FIG. 11A;

FIG. 11 is a flow chart illustrating a method for manufacturing a display panel according to some embodiments of the present disclosure;

FIG. 12 is a flow chart illustrating the sub-steps of performing the step S301 of the method for manufacturing a display panel according to some embodiments of the disclosure; and

FIG. 13 shows a photovoltaic characteristic curve of the optical-electrical conversion layer in a display panel according to some embodiments of the disclosure.

### DETAILED DESCRIPTION

In the following, with reference to the drawings of the embodiments disclosed herein, the technical solutions of the embodiments of the invention will be described in a clear and fully understandable way. It is noted that the described embodiments are merely a portion but not all of the embodiments of the invention. Based on the described embodiments of the invention, those ordinarily skilled in the art can obtain other embodiment(s), which come(s) within the scope sought for protection by the invention.

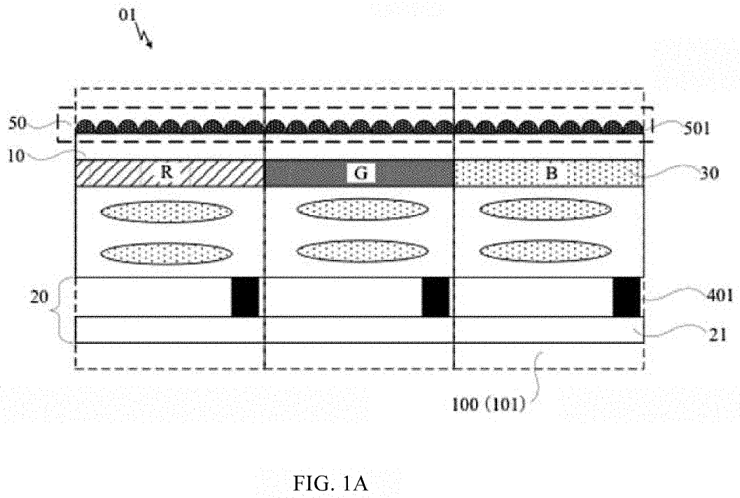

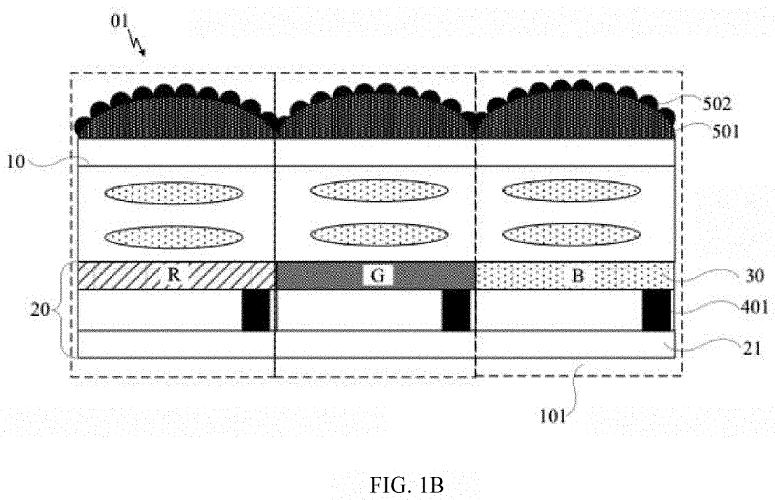

In a first aspect, the present disclosure provides a display panel, which is illustrated in FIG. 1A and FIG. 1B.

As shown in the figures, the display panel 01 comprises an encasing substrate 10 and an array substrate 20, arranged opposing to each other. The array substrate 20 includes a substrate 21. The display panel 01 further includes a color filter layer 30 and a plurality of sub-pixels 100.

The color filter layer 30 can be disposed on a surface of the encasing substrate 10, as shown in FIG. 1A. In this case, the encasing substrate 30 can be called a color film substrate.

Alternatively, the color filter layer 30 can be integrated into the array substrate 20, as shown in FIG. 1B. Integration of the color filter layer 30 with the array substrate 20 can be realized by, for example, a color filter on array (COA) technology.

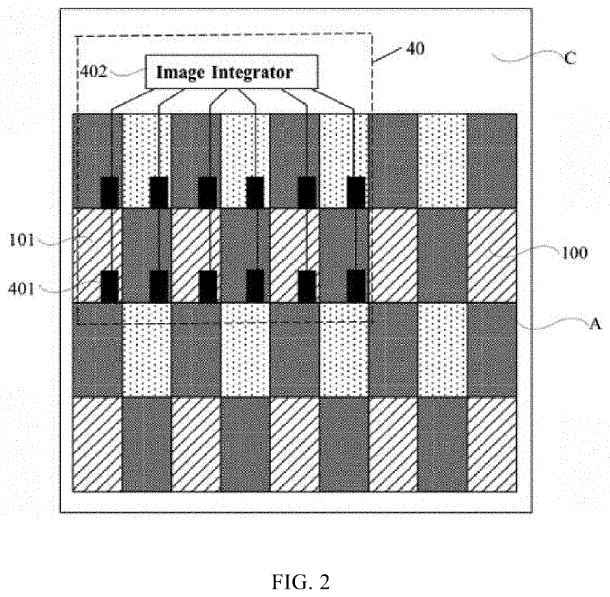

In addition, the display panel 01 further comprises an image capturing assembly 40, as shown in FIG. 2 (in the box having dotted lines). The image capturing assembly 40 includes a plurality of photoelectric converters 401.

The plurality of photoelectric converters 401 are disposed over a surface of the color filter layer 30 that is opposite to a display side of the display panel 01.

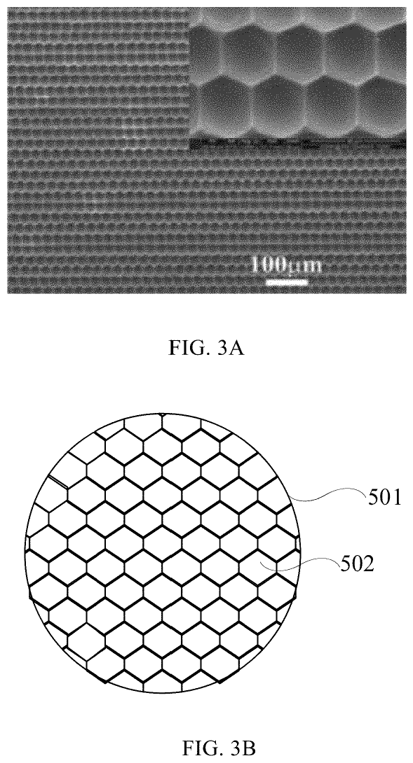

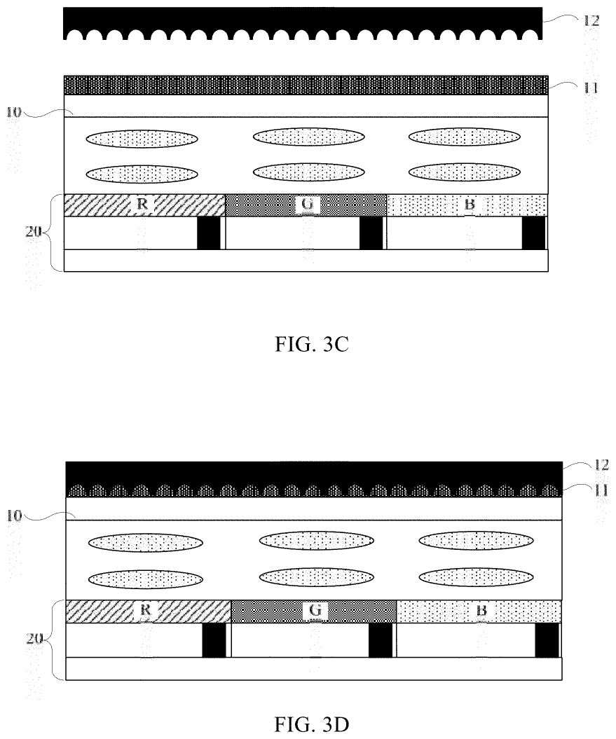

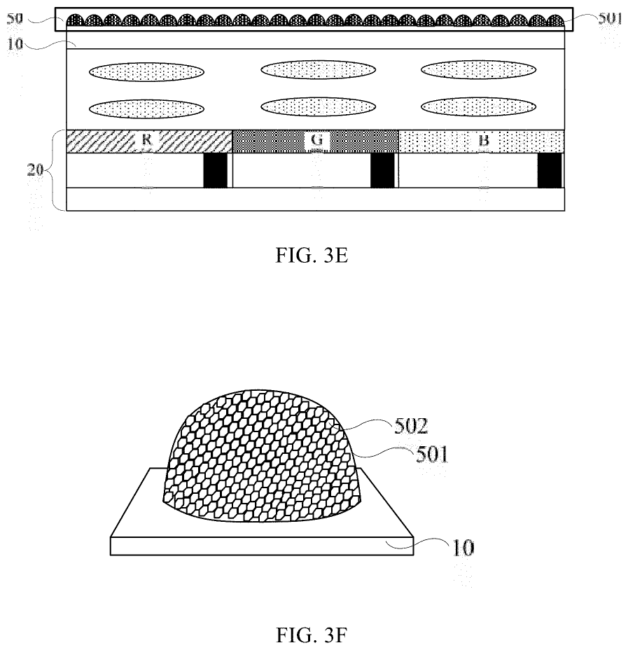

Herein the display side of the display panel 01 is defined as a side of the display panel 01 to which lights emitted from inside the display panel 01 are transmitted (i.e. the light-emitting side of the display panel 01). As illustrated in either FIG. 1A or FIG. 1B, and in any of the following figures showing the cross-sectional view of the display panel 01 (e.g. FIG. 3B, FIG. 3C, and FIG. 3D), the display side of the display panel 01 is substantially the upper side of the display panel 01. In other words, the plurality of photoelectric converters 401 are disposed to be relatively closer to the substrate 21 of the array substrate 20, compared with the color filter layer 30.

Such a configuration allows a light that has entered into the display panel 01 from an environment (i.e. the light from outside the encasing substrate 10 into the display panel 01) to pass through the color filter layer 30 before reaching the plurality of photoelectric converters 401.

Each of the plurality of photoelectric converters 401 is disposed in one of the plurality of sub-pixels 100. In the present disclosure, each of the sub-pixels 100 that contains a photoelectric converter 401 is termed a first sub-pixel 101, as illustrated in FIG. 1A, FIG. 1B, and FIG. 2.

Herein in each first sub-pixel 101, the photoelectric converter 401 disposed therein is employed to convert an optical signal from a light that has entered said first sub-pixel 101 and reached the photoelectric converter 401 into an electric signal, and then to output the electric signal to an image integrator 402 of the image capturing assembly 40. As such, the electric signal is thus an output signal from the photoelectric converter 401.

Further as shown in FIG. 2, the image capturing assembly 40 comprises an image integrator 402 that is electrically coupled, or connected, to each of the plurality of photoelectric converters 401.

The image integrator 402 is configured to receive, and to integrate, the output signal from each of the plurality of photoelectric converters 401, and then to output an image data based on a location of each individual first sub-pixel 101 and a corresponding relationship between the each individual first sub-pixel 101 and each color block in the color filter layer 30 (for example, R, G, B or R, G, B, Y etc.).

Herein the image integrator 402 can receive the output signal from each of the plurality of photoelectric converters 401 in a line-by-line order. Other manners are also possible.

Further as shown in FIG. 2, the display panel 01 can include a display region A and a peripheral region C that is located at a surrounding region of the display region A. Thus the peripheral region C is essentially in a non-display region. The image integrator 402 can be disposed within the peripheral region C as shown in FIG. 2. Alternatively, it can be arranged such that one portion of the image integrator 402 is arranged within the display region A, and another portion of the image integrator 402 is arranged within the peripheral region C (not shown in the drawings).

Taken these above together, each of the plurality of photoelectric converters 401 is disposed in one of the plurality of sub-pixels 100 (i.e. one of first sub-pixels 101).

By such a configuration, during the process of manufacturing the display panel 01, the portion of the image capturing assembly 40 that is employed to achieve an optical-electrical conversion (or photoelectric conversion) can thus be integrated in the display panel 01. On this basis, the image integrator 402 can receive, and integrate, the output signal from each photoelectric converter 401, and then output the image data based on the integrated output signal, thereby realizing an image capturing function (i.e. camera function).

Consequently, because the image capturing assembly 40 with a camera function is integrated in the display panel 01 as disclosed herein, there is no need to separately purchase and bond components with camera function with the display panels being manufactured, thereby this configuration is beneficial for the cost reduction and the thin-bezel design for the display apparatuses.

On this basis, in order to improve the shooting effects (i.e. photographing effects, or camera functionality) and to ensure that images that have been captured have a wide view angle so that the sensual experiences of the users can be improved, optionally, the display panel 01 can further include an optical function layer 50 (i.e. a lens layer), disposed over a light-emitting surface of the color filter layer 30 (i.e. the upper surface of the color filter layer 30 as shown in FIG. 1A).

The optical function layer 50 is configured to allows as much light as possible to enter into the display panel 01 to thereby result in an increased view angle of images to be captured by the display panel 01 compared with display panel 01 having no optical function layer 50 arranged therein.

The optical function layer 50 can include one or more levels of microlenses, depending on practical needs. In some embodiments, the optical function layer 50 can comprise one level of microlenses (termed a first-level of microlenses), as illustrated in FIG. 1A. In some other embodiments, the optical function layer 50 can include two levels of microlenses, wherein a second level of microlenses can be disposed on a surface of a first-level microlenses, as illustrated in FIG. 1B, which are configured to further increase the wide view angle of the images to be captured. Herein the first level of microlenses and the second level of microlenses are substantially arranged in a level-on-level manner.

It is noted that based on the same principle as described above, the optical function layer 50 can also include more than two levels of microlenses in some other embodiments, disposed in a similarly level-on-level manner.

In the embodiments of the display panel as indicated in FIG. 1A, the optical function layer 50 includes only one level of microlenses, and to be more specific, includes a plurality of first-level microlenses 501, wherein the plurality of first-level microlenses 501 are configured to positionally correspond to the plurality of first sub-pixels 101. In other words, an orthographic projection of each first sub-pixel 101 on the substrate 21 of the array substrate 20 is configured to cover an orthographic projection of a sub-set of the plurality of first-level microlenses 501 on the substrate 21.

Each of the plurality of first-level microlenses 501 can have a diameter of around 100 μm, and the plurality of first-level microlenses 501 can be arranged to be substantially equally spaced apart from one another at a distance.

Herein it is noted that the configuration of the plurality of first-level microlenses 50 in the optical function layer 50, such as a size of each first-level microlens 501, a distance between every two first-level microlenses 501, a ratio of the number of first-level microlenses 501 with the first sub-pixel 101, and the specific arrangement of the plurality of first-level microlenses 50, can vary depending on different practical needs.

For example, the distance between every two first-level microlenses 501 can vary, having a range of several micrometers to tens of micrometers. There are no limitations herein.

The corresponding relationship between the plurality of first sub-pixels 101 and the plurality of first-level microlenses 501 can also vary depending on practical needs.

In the embodiment as illustrated in FIG. 1B, the plurality of first sub-pixels 101 and the plurality of first-level microlenses 501 has a corresponding relationship of 1:1 (i.e. one first-level microlens is configured or arranged within one corresponding first sub-pixel 101).

In another embodiment (not shown in the drawings), the corresponding relationship between the plurality of first sub-pixels 101 and the plurality of first-level microlenses 501 is 1:3 (i.e. three first-level microlenses 501 are arranged within one corresponding first sub-pixel 101).

In yet another embodiment as illustrated in FIG. 1A, the corresponding relationship between the plurality of first sub-pixels 101 and the plurality of first-level microlenses 501 is 1:9 (i.e. nine first-level microlenses 501 are configured in one corresponding first sub-pixel 101).

It is noted that these corresponding relationships between the plurality of first sub-pixels 101 and the plurality of first-level microlenses 501 as illustrated in the above embodiments shall be construed as illustrating examples, and as such do not impose a limitation to the scope of the disclosure.

Each of the plurality of first-level microlenses 501 is configured to have a surface that is convex in a direction away from the array substrate 20 (i.e. in the light-emitting direction), thereby increasing a contact area of the display panel 01 with the lights from an outside (i.e. the environment).

Such a configuration allows more light to enter into the display panel 01. Therefore, as long as the manufacturing cost is at an acceptable level, the higher the number of the plurality of first-level microlenses 501 that are configured within each of the plurality of first sub-pixels 101, the larger the contact area the display panel 01 has with the light from the outside/environment, the more the light entering the display panel 01, and the wider the capture range for the plurality of photoelectric converters 401.

Consequently, the images that are captured by the display panel 01 can have a relatively wide view angle and a relatively large depth of field.

On this basis, in order to further increase the wide view angle of the images captured, a plurality of second-level microlenses 502 can be further arranged/configured over a side of the plurality of first-level microlens 501 that is away from the color filter layer 30.

In the embodiment of the display panel as shown in FIG. 1B, the optical function layer 50 includes two levels of microlenses, and to be more specific, includes a first-level of microlenses and a second-level of microlenses, wherein the second-level of microlenses is disposed on a surface of the first-level of microlenses that is on the display side (i.e. the light-emitting side) of the display panel 01.

Specifically, the optical function layer 50 in the display panel as shown in FIG. 1B includes a plurality of first-level microlenses. Each first-level microlens 501 is configured to correspond to one first sub-pixel 101 (i.e. the plurality of first sub-pixels 101 and the plurality of first-level microlenses 501 that are arranged therein has a corresponding relationship of 1:1), and each first-level microlens 501 is further provided with a plurality of second-level microlenses 502, which are arranged over an outer side (i.e. the light-emitting side) of the each first-level microlens 501 that is away from the color filter layer 30.

Specifically, as illustrated in FIG. 1B, the plurality of second-level microlenses 502 having a diameter of several micrometers are arranged/configured over each first-level microlenses 501 with a diameter of several hundred micrometers.

As such, the plurality of second-level microlenses 502 that are convex in a direction away from the array substrate 20, are substantially arranged in in an orderly matrix over a curved outer surface of each of the plurality of first-level microlenses 501, thereby forming a substantially compound eye-like structure as illustrated in FIG. 3A and FIG. 3B.

Such a configuration further increases the amount of light entering in each of the plurality of first sub-pixels 101, causing a further enlarged capture range of the photoelectric converters 401 and in turn leading to an increased view angle and an increased depth of field of the images that are captured by the display panel 01.

Herein, the plurality of first-level microlenses 501 and the plurality of second-level microlenses 502 can be fabricated by a laser assisted wet etching process or a nanoimprinting process.

In the following, with reference to several illustrating embodiments, a method for fabricating the plurality of first-level microlenses 501 through a nanoimprinting process is described in detail.

Specifically, a resin layer 11 is first formed over the surface of the encasing substrate 10 that is opposite to the array substrate 20, as illustrated in FIG. 3C.

Next, as shown in FIG. 3D, in a vacuum environment, a mold 12 having a plurality of concave structures on a concave side thereof can be operated such that the concave side of the mold 12 is pressed onto the resin layer 11 through a hot pressing process. Each of the plurality of concave structures of the mold 12 has a shape that substantially matches the shape of each of the plurality of first-level microlenses 501.

Then, through a demolding process, the mold 12 is removed to thereby form an optical function layer 50 having a plurality of first-level microlenses 501 that are arranged in in a matrix, as illustrated in FIG. 3E.

In addition, the method for manufacturing the optical function layer 50 having a plurality of first-level microlenses 501 and a plurality of second-level microlenses 502 (as illustrated in FIG. 1B) is substantially same as the method as described above, with a difference that each of the plurality of concave structures in the mold 12 matches the shape of each single first-level microlens 501 and the shapes of the plurality of second-level microlenses 502 on the outer surface of the first-level microlens 501, as illustrated in FIG. 3F.

In the following, in order to achieve thin-bezel design of the display apparatus, the configuration method of the first sub-pixels 101 having a photoelectric converter 401 will be described in detail with examples.

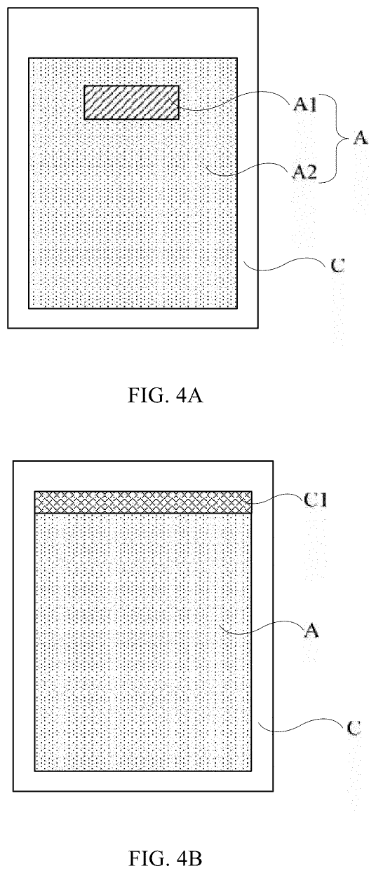

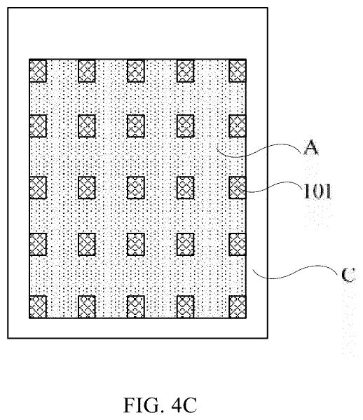

In one embodiment of the display panel as illustrated in FIG. 4A, a display region A of the display panel can include at least one image capturing sub-region A1 (i.e. camera area) and a display sub-region A2 (i.e. active area) surrounding the at least one image capturing sub-regions A1. In each of the at least one image capturing sub-region A1, each of the sub-pixels therein is configured to be a first sub-pixel 101 (i.e. the sub-pixel having a photoelectric converter 401).

It is noted that the at least one image capturing sub-region A1 can be arranged in any location within the display region A. Yet in order to reduce an influence on the images that are displayed in the display region A of the display panel, optionally each of the at least one image capturing sub-region A1 can be arranged as close to the peripheral region C as possible.

In another embodiment of the display panel as shown in FIG. 4B, the peripheral region C further includes a dummy display sub-region C1, and the plurality of first sub-pixels 101 can all be arranged within the dummy display sub-region C1.

Herein it should be noted that in order to maintain the scan signals or the data signals inputted into the display region A stable, several lines of dummy sub-pixels are usually arranged at locations in the peripheral region C that are adjacent to the display region A, and are configured to have a structure similar to the sub-pixels within the display region A.

These dummy sub-pixels are configured to display normally, however, lights emitted by each of these dummy sub-pixels are blocked by the bezel of the display apparatus. As such, if the driving components for the display panel, such as a gate driver and a source driver, which are configured to provide signals to the sub-pixels in the display region A, are disposed at the surrounding region C, the signals can be first transmitted to the dummy sub-pixels, and after the signal transmission becomes stable, the signals can then be transmitted to the sub-pixels in the display region A.

As such, if the plurality of first sub-pixels are all located within the dummy display sub-region C1, the influence to the display region A can be effectively avoided. Therefore, in order for the photoelectric converters 401 that are each configured in each of the plurality of first sub-pixels within the dummy display sub-region C1 to be able to receive environmental lights that enter into the display panel 01, a plurality of light-transmitting holes need to be arranged at locations in the dummy display sub-region C1 in the bezel of the display panel that are each configured to correspond to one photoelectric converter 401.

It is noted that there are no limitations to the shape and size of the plurality of light-transmitting holes, as long as each of the photoelectric converters 401 can receive the environmental lights entering into each of the corresponding first sub-pixels 101.

In addition, in order to avoid an influence to the display region A, the plurality of first sub-pixels as mentioned above can also be configured at any locations in the peripheral region C. However, as a result, a portion of the wiring region and bonding region within the peripheral region C will be occupied.

As such, in order to configure driving circuits for the display panel, the area of the peripheral region C will have to be increased. For the above reason, in order to realize a thin-bezel design and to avoid an influence to the display region A, optionally, the plurality of first sub-pixels 101 are all arranged within the dummy display sub-region C1.

Alternatively, in yet another embodiment of the display panel as shown in FIG. 4C, the plurality of first sub-pixels 101 are evenly distributed within the display region A. As a result, all of the photoelectric converters 401 in the image capturing assembly 40 can evenly capture the environmental lights entering into the display panel 01.

Optionally, the photoelectric converters 401 in the first sub-pixels 101 can be arranged in a periodic array of about 10 μm-5000 μm (i.e. every two neighboring photoelectric converters 401 along a row direction or along a column direction have a substantially equal distance of around 10 μm˜5000 μm).

In both the embodiments as illustrated in FIG. 4A and FIG. 4B, the plurality of sub-pixels 101 are relatively concentrated. As such, in order to reduce the difficulty in, and to improve the accuracy of, the manufacturing process of the display panel, optionally, the optical function layer 50 can be configured to completely cover each of the at least one image capturing sub-region A1 in the embodiment as illustrated in FIG. 4A, or to completely cover the dummy display sub-region C1 in the embodiment as illustrated in FIG. 4B.

In addition, in the embodiments as illustrated in FIG. 4A and FIG. 4C, because all first sub-pixels 101 are arranged within the display region A, the area of the peripheral region C occupied by the image capturing assembly 40 can be reduced, therefore it is advantageous to a thin-bezel or ultrathin-bezel design, in turn potentially leading to a full screen display for the display panel.

Regarding the embodiments of the display panel as illustrated in FIG. 4A, FIG. 4B and FIG. 4C, the configuration of the plurality of first sub-pixels 101, the structure and connection of the photoelectric converters 401 in the plurality of first sub-pixels 101 are as follows.

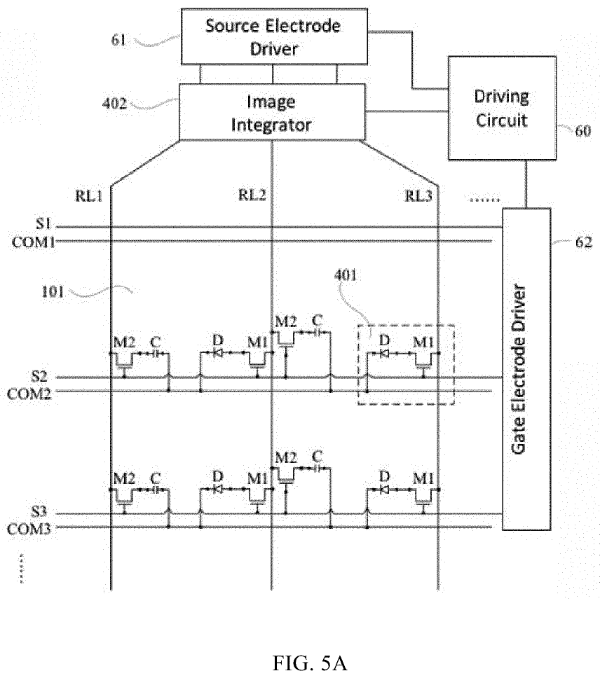

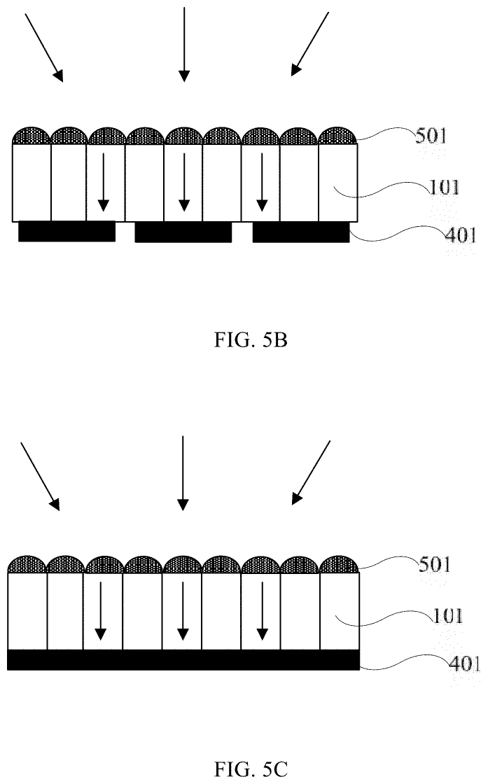

Specifically, as shown in FIG. 5A, a plurality of read lines RL (including RL1, RL2, RL3 . . . ), a plurality of scan lines S (including S1, S2, S3 . . . ) and a plurality of common electrode lines COM (COM1, COM2, COM3 . . . ) are arranged within the display region A.

Each photoelectric converter 401 is electrically coupled or connected to a read line RL, a scan line D, and a common electrode line COM. As such, under control of the scan line S and the common electrode line COM coupled thereto, each photoelectric converter 401 can perform an optical-electrical conversion to a light entering into the first sub-pixel 101 where each photoelectric converter 401 is disposed, and can then output a conversion result (i.e. the electric signal corresponding to the optical signal from the light) to the read line RL coupled thereto.

In addition, the image integrator 402 is electrically coupled or connected to each of the plurality of read lines RL, and the image integrator 402 is configured to receive electric signals transmitted by the plurality of read lines RL, to integrate the electric signals into an image data, and to output the image data, thereby completing the image capturing process of the image capturing assembly 40.

On the above basis, in order to further improve the transmittance of the display region A and to reduce the area of the light-blocking region, optionally, if the display region A and the dummy display sub-region C1 contains a plurality of gate lines (Gate) and a plurality of data lines (Data) (not shown in figures) that cross to one another, the plurality of scan line S and the plurality of gate lines (Gate) are configured to be shared, the read lines RL and the data lines (Data) are also configured to be shared.

In other words, in the display panel disclosed herein, a plurality of signal lines are configured such that each signal line serves as a dual-functional signal line as both a scan line S and a gate line (Gate), or as a dual-functional signal line as both a read line RL and a data line (Data).

By this above configuration, there is no need to manufacture the plurality of scan lines S and the plurality of read lines RL, resulting in a simplified manufacturing process for the display panel and an improved transmittance of the display region A.

In the embodiments of the display panel as described above, when the display panel 01 is displaying a frame of image, the image frame can be divided into a displaying stage and an image capturing stage.

During the displaying stage, the sub-pixels in the display region A and the dummy sub-pixels in the dummy display sub-region C1 receive the scan signals for the gate electrodes and data signals to thereby display normal images.

During the image capturing stage, the image capturing assembly 40 captures images.

As such, the display panel 01 further comprises a driving circuit 60, which is electrically coupled or connected to the image integrator 402, a source electrode driver 61 and a gate electrode driver 62.

The driving circuit 60 is configured to receive the image data outputted by the image integrator 402, and then to output control signals to the source electrode driver 61 and the gate electrode driver 62 to thereby control the display panel to display the image data.

Each photoelectric converter 401 comprises a phototransistor M1 and a commutation diode D. A gate electrode of the phototransistor M1 is coupled to the scan line S, a first electrode of the phototransistor M1 is coupled to the read line RL, and a second electrode is coupled to an anode of the commutation diode D. A cathode of the commutation diode D is coupled to the common electrode line COM.

As such, when a light entering into the first sub-pixel 101 reaches the phototransistor M1, the phototransistor M1 can convert the optical signal from the light, and can then output a current signal to the read line RL.

It should be noted that the description of the embodiment of the display panel is based on an example where the photoelectric converters 401 and the first sub-pixels 101 can have a corresponding relationship of 1:1 (i.e. one photoelectric converter 401 is configured in one first sub-pixel 101), as illustrated in FIG. 5A.

Alternatively, the photoelectric converters 401 and the first sub-pixels 101 can have a corresponding relationship of 1:3, as illustrated in FIG. 5B (i.e. three sub-pixels 101 share one photoelectric converter 401). Alternatively, the photoelectric converters 401 and the first sub-pixels 101 can have a corresponding relationship of 1:9, as illustrated in FIG. 5C (i.e. nine sub-pixels 101 share one photoelectric converter 401. Other corresponding relationship, such as 1:2 or 1:6, may also be adopted, and there are no limitations herein.

On this basis, if more than one first sub-pixel 101 shares a photoelectric converter 401, the photoelectric converter 401 can be configured within one of the more than one first sub-pixel 101.

Alternatively, as shown in FIG. 5B or FIG. 5C, a photoelectric converter 401 may be configured inside each of the more than one first sub-pixel 101. In this case, the phototransistor M1 in each photoelectric converter 401 can be configured to share a read line RL.

In addition, in order to achieve normal display, as shown in FIG. 5A, each of the sub-pixels in the display panel 01 is further configured with a switch transistors M2 and a liquid crystal capacitor C.

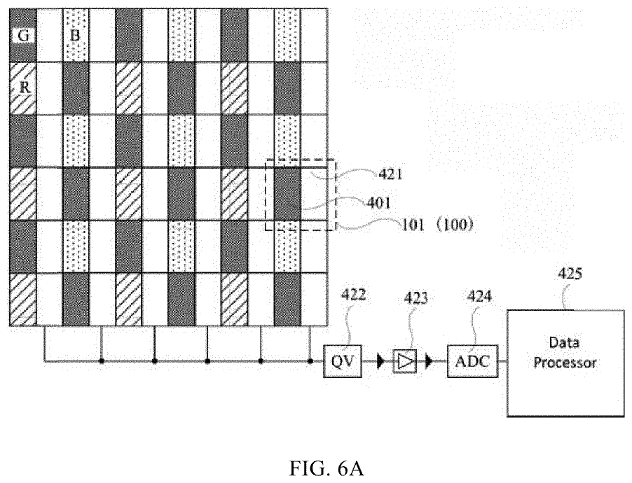

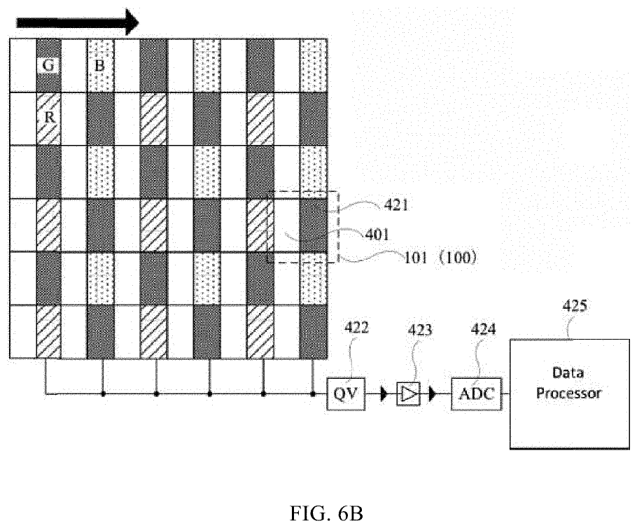

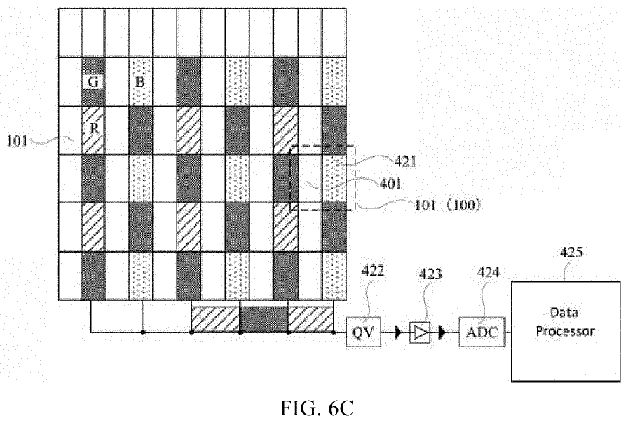

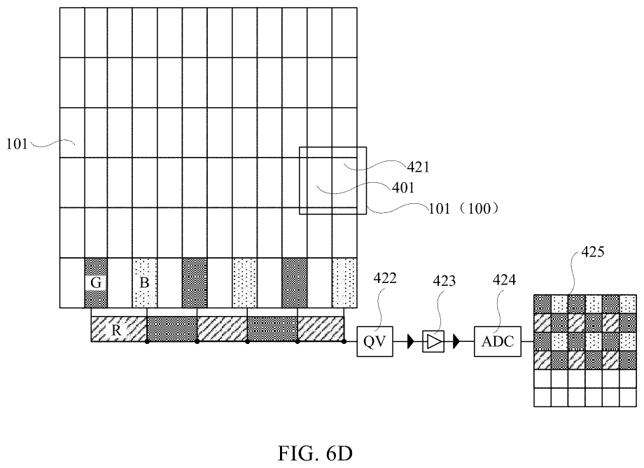

On this basis, as shown in FIG. 6A, FIG. 6B, FIG. 6C and FIG. 6D, the image integrator 402 comprises an electron-to-voltage converter (QV) 422, an amplifier 423, an analog-to-digital converter (ADC) 424, a data processor 425 and a plurality of shift registers 421.

Each shift register 421 is arranged within a first sub-pixel 101. Each shift register 421 is electrically coupled or connected to a corresponding photoelectric converter 401, and is configured to cache the output signals therefrom. Specifically, after the photoelectric converter 401 completes the optical-electrical conversion, the current signal after the conversion is stored in the shift register 421 coupled to the photoelectric converter 401 along a direction of the arrow as shown in FIG. 6B.

The electron-to-voltage converter 422 is electrically coupled to each shift register 421, as shown in FIG. 6C. The electron-to-voltage converter 422 is configured to convert the current signal cached in each shift register 421 into a voltage signal in a line-by-line manner.

The amplifier 423 is electrically coupled to the electron-to-voltage converter 422. The amplifier 423 is configured to amplify the voltage signals from the electron-to-voltage converter 422.

The analog-to-digital converter 424 is electrically coupled to the amplifier 423. The analog-to-digital converter 424 is configured to convert the voltage signals from the amplifier 423, which are originally in the form of analog signals, into digital signals.

The data processor 425 is electrically coupled to the analog-to-digital converter 424. The data processor 425 is employed to integrate the digital signals received from the analog-to-digital converter 424, and to form a planar dot array as shown in FIG. 6D based on a location of each first sub-pixel 101 and a relationship between each first sub-pixel 101 and a corresponding color block (for example, R, G, or B) in the color filter layer 30. Herein, each dot in the planar dot array corresponds to a sub-pixel of an image frame captured by the image capturing assembly 40.

It is noted that in the disclosure, the various configurations of the color filter layer 30 is described with G-R-G-B as an illustrating example. As shown in FIG. 6D, every four neighboring dots in the planar dot array form a pixel. In each pixel, a greyscale of each sub-pixel is configured to match a binary data corresponding to a quantity of light received by the corresponding photoelectric converter 401.

After the data processor 425 completes the image integration process to thereby form an integrated image data as described above, the data processor 425 is further configured to output the integrated image data to the driving circuit 60 shown in FIG. 5A.

In a second aspect, the present disclosure further provides a display apparatus, which includes a display panel according to any one of the embodiments as described above. As such, the advantages of the display apparatus are substantially the same as the display panel as mentioned above, and will not be repeated herein.

It should be noted that the display apparatus disclosed herein can include a liquid crystal display (LCD) device or an organic light-emitting diode (OLED) display device. For example, the display apparatus can be any product or component that has a display function, such as a liquid display (LCD) device, a liquid crystal television, a digital photo frame, a digital camera, a mobile phone, or a tablet.

In a third aspect, the present disclosure further provides a method for driving a display panel according to any one of the embodiments as described above.

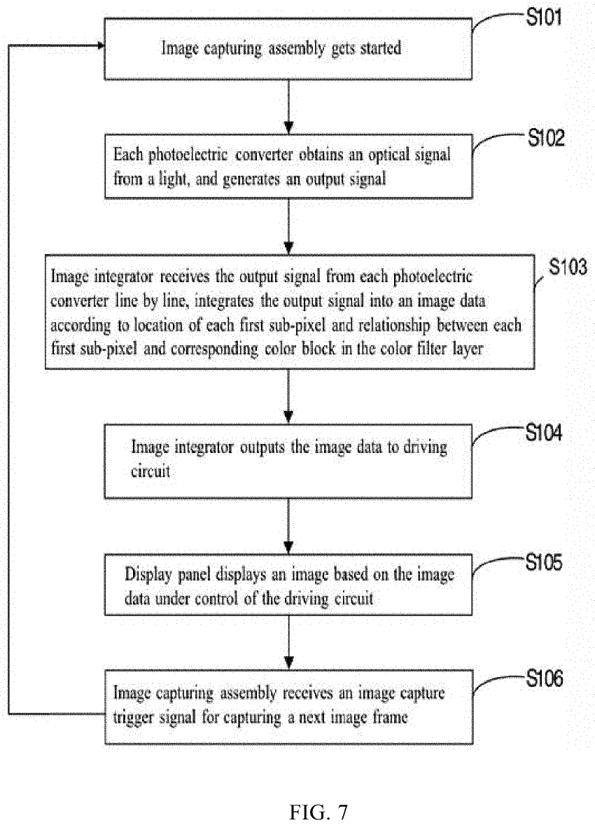

As shown in FIG. 7, the method comprises the following steps:

S101: the image capturing assembly 40 gets started.

S102: each of the photoelectric converters 401 converts an optical signal from a light that transmits through one of a plurality of color blocks and reaches thereupon into an electrical signal; and

Specifically, each photoelectric converter 401 as illustrated in FIG. 1A or FIG. 1B converts the optical signal of the light entering into the first sub-pixel 101 into an electric signal (i.e. an output signal).

Herein the display panel optionally comprises an optical function layer 50, which can have a plurality of first-level microlenses 501, or have a plurality of first-level microlenses 501 plus a plurality of second-level microlenses 502 arranged in a matrix over the plurality of first-level microlenses 501.

The optical function layer 50 can increase the quantity of light entering into the photoelectric converter 401 thus ensuring that the photoelectric converters 401 can have a relatively wide capture range.

S103: the image integrator 402 as shown in FIG. 2 receives the electrical signal (i.e. output signal) from each photoelectric converter 401 in a line-by-line manner, integrates the output signals into an image data according to the location of each first sub-pixel 101 and a relationship between each first sub-pixel 101 and a corresponding color block in the color filter layer.

Herein, according to some embodiments, the image integrator 402 can include the electron-to-voltage converter 422, the amplifier 423, the analog-digital converter 424, the data processor 425 and the plurality of shift registers 421, as shown in FIG. 6A, FIG. 6B, FIG. 6C and FIG. 6D. The working process of the image integrator 402 is substantially same as described above, and will not be repeated herein.

S104: the image integrator 402 outputs the image data to the driving circuit 60 as shown in FIG. 5A.

S105: the display panel 01 displays an image based on the image data under control of the driving circuit 60.

Specifically, the driving circuit 60 sends control signals to the source electrode driver 61 and the gate electrode driver 62, allowing the gate electrode driver 62 to output gate electrode scan signals to the gate lines (Gate) in a line-by-line manner, and allowing the data lines (Data) to charge each sub-pixel 100.

Further, prior to executing the aforementioned step S101, the method can further comprise:

S106: the image capturing assembly 40 receives an image capture trigger signal for capturing a next image frame.

In summary, in the display panel as described above, each photoelectric converter 401 is arranged in one sub-pixel 100. As such, during the process of manufacturing the display panel 01, one portion of the image capturing assembly 40 that is employed to achieve optical-electrical conversion can be integrated into the display panel 01. The image integrator 401 can integrate the output signals received from each photoelectric converter 401 and can then output the image data, ultimately realizing an image capturing function for the display panel.

Because the image capturing assembly having a camera function can be integrated into the display panel disclosed herein, there is no need to separately purchase components that have camera function, thereby resulting in a reduce cost for, and benefiting the thin-bezel design of, the display panel.

In the embodiments where the display region A and the dummy display sub-region C1 comprise the gate lines (Gate) and the data lines (Data) (not shown in figures) crossing one another, the scan lines S and the gate lines (Gate) can be shared, and the read lines RL and the data lines (Data) can be shared.

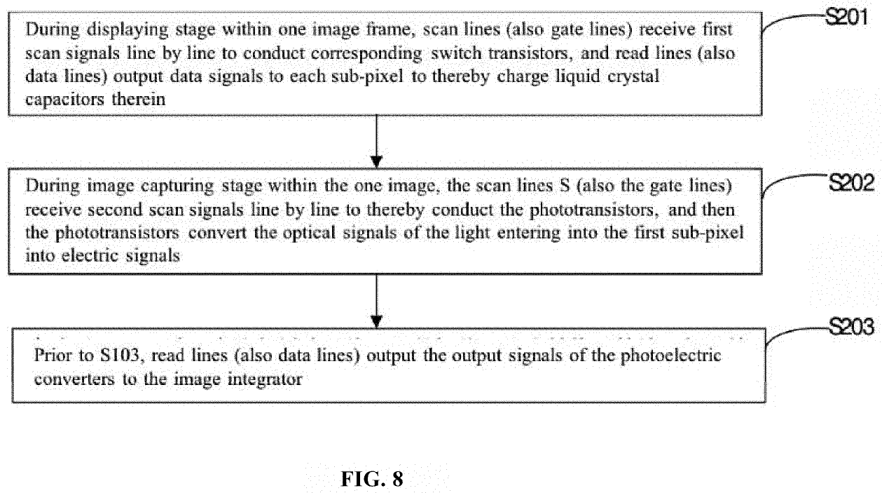

In this case, as shown in FIG. 8, within one image frame, the method for driving a display panel comprises:

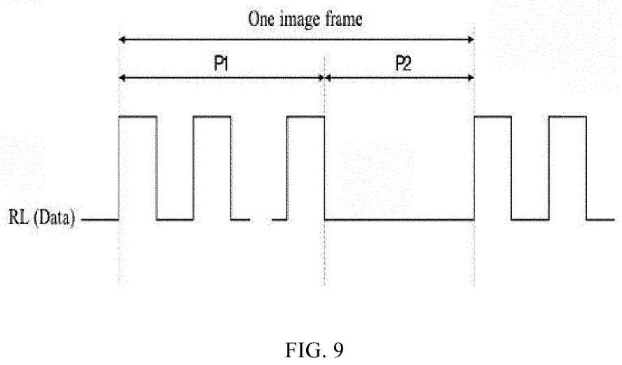

S201: during a displaying stage P1 within the one image frame as shown in FIG. 9, the scan lines S (also the gate lines (Gate)) receive first scan signals in a line-by-line manner to thereby conduct the corresponding switch transistors M2, and then the read lines RL (also the data lines (Data)) output data signals to each sub-pixel 100 to thereby charge the liquid crystal capacitor C in each sub-pixel 100.

S202: During an image capturing stage P2 within the one image frame as shown in FIG. 9, the scan lines S (also the gate lines (Gate)) receive second scan signals in a line-by-line manner to thereby conduct the phototransistors M1, and then the phototransistors M1 in the photoelectric converters 401 convert the optical signals of the light entering into the first sub-pixel 101 into electric signals.

After the steps S201 and S202, according to some embodiments of the method, prior to the step S103, the method further comprises:

S203: the read lines RL (also the data lines (Data)) output the output signals of the photoelectric converters 401 to the image integrator 402.

In a fourth aspect, the present disclosure further provides an array substrate 20 in the display panel 01 as described above.

The array substrate 20 includes a phototransistor M1 and a switch transistor M2. The phototransistor M1 is part of a photoelectric converter 401, which is disposed in at least one sub-pixel 100.

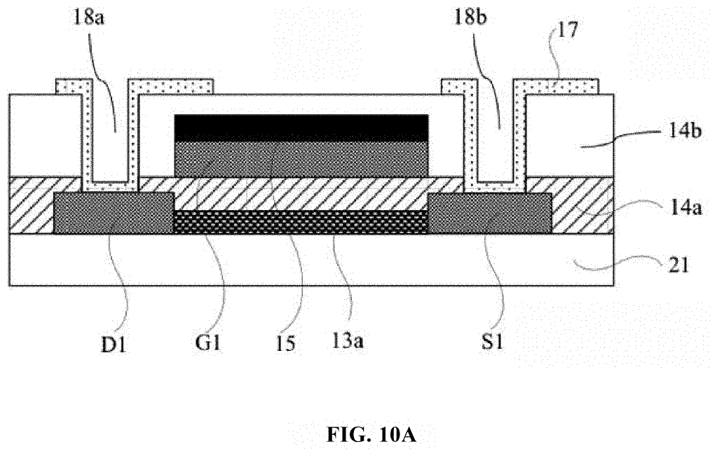

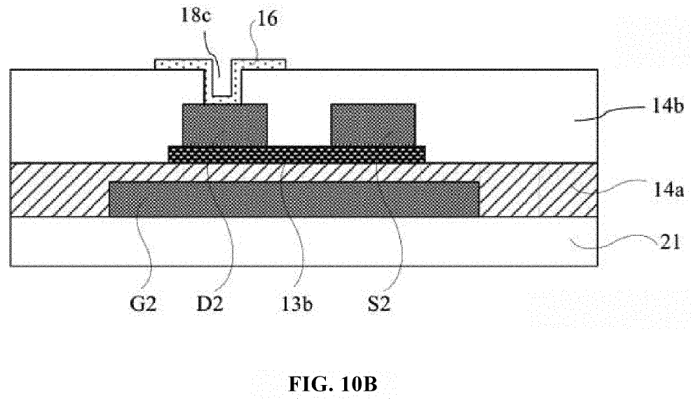

As illustrated in FIG. 10A, the phototransistor M1 comprises a substrate 21, a first active layer 13a, a source electrode S1, a drain electrode D1, a first insulating layer 14a, a gate electrode G1, an optical-electrical conversion layer 15, a second insulating layer 14b, and two signal lead lines 17.

As shown in FIG. 10A, the first active layer 13a, the source electrode S1, and the drain electrode D1 are each disposed on an upper surface of the substrate 21. The first active layer 13a is sandwiched between the source electrode S1 and the drain electrode D1. The first insulating layer 14a is disposed over the first active layer 13a, the source electrode S1, and the drain electrode D1.

The gate electrode G1 is disposed over an upper surface of the first insulating layer 14a. The optical-electrical conversion layer 15 is disposed over the gate electrode G1. The second insulating layer 14b is disposed over an upper surface of the optical-electrical conversion layer 15 to thereby cover, and provide an insulation to, the optical-electrical conversion layer 15 and the gate electrode G1. The two signal lead lines 17 are disposed on an upper surface of the second insulating layer 14b.

One of the two signal lead lines 17 is electrically coupled to a first electrode (e.g. a source electrode S1) of a phototransistor M1 through a first via 18a disposed through the second insulating layer 14b and the first insulating layer 14a to thereby allow the first electrode of the phototransistor M1 to be electrically connected to a corresponding read line RL as shown in FIG. 5A.

Another of the two signal lead lines 17 is electrically coupled to a second electrode (e.g. a drain electrode D1) of the phototransistors M1 through a second via 18b disposed through the second insulating layer 14b and the first insulating layer 14a to thereby allow the second electrode of the phototransistor M1 to be electrically connected to an anode of a commutation diode D.

As illustrated in FIG. 10B, the switch transistor M2 comprises a substrate 21, a gate electrode G2, a first insulating layer 14a, a second active layer 13b, a source electrode S2, a drain electrode D2, a second insulating layer 14b, and a pixel electrode 16.

The gate electrode G2 of the switch transistor M2 is disposed on an upper surface of the substrate 21. The first insulating layer 14a is disposed over, and provides an insulation to, the gate electrode G2. The second active layer 13b is disposed over an upper surface of the first insulating layer 14a.

The drain electrode D2 and the source electrode S2 of the switch transistor M2 are disposed on an upper surface of the second active layer 13b and are separated from one another. The second insulating layer 14b is disposed over, and provides insulation to, the second active layer 13b, and the drain electrode D2, and the source electrode S2.

The pixel electrode 16 is disposed on an upper surface of the second insulating layer 14b, and is electrically coupled to the drain electrode D2 through a via 18c in the second insulating layer 14b.

It is further configured such that the various film layers of the phototransistor M1 and the various film layers of the switch transistor M2 can have a substantially same composition and/or can be at substantially same layers, and can thus be fabricated during a same processes in order to simplify the manufacturing process and reduce the manufacturing cost.

Specifically, as shown in FIG. 10A and FIG. 10B, the source electrode S1 and the drain electrode D1 of the phototransistor M1 can have a substantially same composition, and can be at a substantially same layer, as the gate electrodes G2 of the switch transistors M2.

Such a configuration allows the source electrode S1 and the drain electrode D1 of the phototransistor M1 and the gate electrodes G2 of the switch transistors M2 to be fabricated by forming a first metal electrode layer over the substrate, followed by patterning the first metal electrode layer during manufacturing of the array substrate.

Similarly, the first insulating layer 14a disposed over the first active layer 13a, the source electrode S1, and the drain electrode D1 in the phototransistor M1 can have a substantially same composition, and can be at a substantially same layer, as the first insulating layer 14a disposed over the gate electrode G2 in the switch transistors M2.

The gate electrodes G1 of the phototransistors M1 can have a substantially same composition, and can be at a substantially same layer, as the source electrodes S2 and the drain electrodes D2 of the switch transistors M2, and they can be fabricated by forming a second metal electrode layer followed by patterning the second metal electrode layer during the manufacturing of the array substrate.

Such a configuration allows gate electrodes G1 of the phototransistors M1 and the source electrodes S2 and the drain electrodes D2 of the switch transistors M2 to be fabricated by forming the second metal electrode layer, followed by patterning the second metal electrode layer during manufacturing of the array substrate.

The first active layer 13a of the phototransistors M1 can have a substantially same composition as the second active layer 13b of the switch transistors M2, and both can have a composition of a semi-conductive material, such as amorphous silicon(a-Si) or low temperature poly-silicon.

The second insulating layer 14b disposed over an upper surface of the optical-electrical conversion layer 15 in the phototransistor M1 can have a substantially same composition, and can be at a substantially same layer, as the second insulating layer 14b disposed over the second active layer 13b, and the drain electrode D2, and the source electrode S2 in the switch transistors M2.

The two signal lead lines 17 that are disposed on an upper surface of the second insulating layer 14b in the phototransistor M1 can have a substantially same composition, and can be at a substantially same layer, as the pixel electrode 16 disposed on an upper surface of the second insulating layer 14b in the switch transistor M2.

Such a configuration allows the two signal lead lines 17 of the phototransistor M1 and the pixel electrode 16 of the switch transistors M2 to be fabricated by forming a transparent conductive layer over the second insulating layer 14b, followed by patterning the transparent conductive layer during manufacturing of the array substrate.

It is noted that the embodiments as described above and illustrated in FIG. 10A and FIG. 10B shall not be construed as limitations to the scope of the disclosure, and other composition and structure are also possible.

In a fifth aspect, the present disclosure further provides a method for manufacturing the aforementioned display panels 01. The manufacturing method includes a process for forming a plurality of sub-pixels 100.

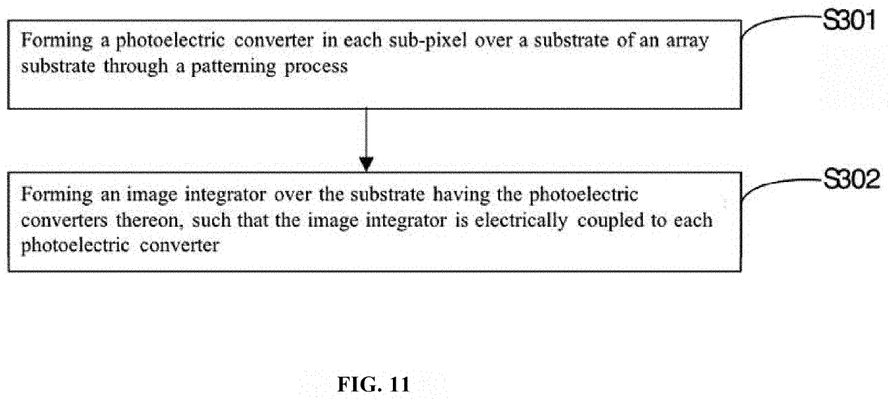

In embodiments where a display panel 01 comprises an array substrate 20 and an encasing substrate 10 arranged to be opposite to one another, as shown in FIG. 11, the manufacturing method comprises the following steps:

S301: forming a photoelectric converter 401 in each sub-pixel 100 over the substrate 21 of the array substrate 20, as illustrated in FIG. 1A or FIG. 1B.

Herein the photoelectric converter 401 can be formed through a patterning process.

S302: forming the image integrator 402 over the substrate 21 having the photoelectric converters 401 thereon, such that the image integrator 401 is electrically coupled to each photoelectric converter 401.

This manufacturing method has the same beneficial effects as the display panels as described above, and will not be repeated herein.

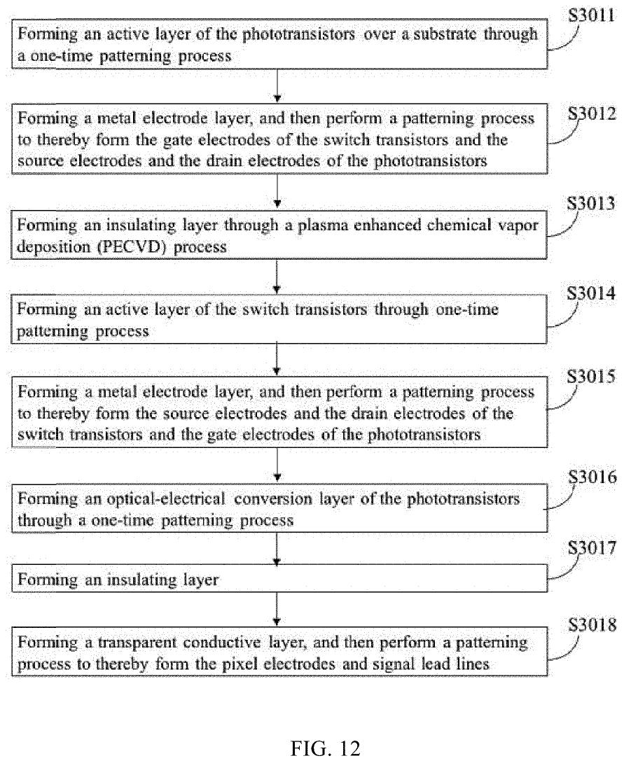

On this basis, as shown in FIG. 12, in embodiments where each photoelectric converter 401 comprises the phototransistor M1, and each switch transistor M2 coupled to the pixel electrodes is arranged in the one sub-pixel 100, the step S301 (i.e. forming a photoelectric converter 401 in each sub-pixel 100 over the substrate 21 of the array substrate 20) can include:

S3011: forming a first active layer 13a of the phototransistors M1 as shown in FIG. 11A over the substrate 21 through a one-time patterning process.

Herein the first active layer 13a of the phototransistors M1 can have a composition of a semi-conductive material, such as amorphous silicon(a-Si) or low temperature poly-silicon.

Herein the patterning process may include a photolithography process, or a photolithography process followed by an etching process, or may include another process capable of forming a preset pattern, such as a printing process or an ink-jet printing process.

The photolithography process as mentioned above is referred to as a process for forming a preset pattern utilizing photoresist, mask, and exposure machine, which can include the processes of film formation, exposure, development, and so on. The specific patterning process can be selected based on practical needs.

It is noted that the one-time patterning process according to some embodiments of the disclosure is described herein with an example in which the different exposure regions are formed through the one-time mask exposure process, and the preset pattern is obtained through multiple times of removal processes such as etching and ashing.

S3012: over the substrate 21 having the first active layer 13a of the phototransistors M1 thereupon, forming a first metal electrode layer, and then perform a patterning process over the first metal electrode layer to thereby form the gate electrodes G2 of the switch transistors M2 (as shown in FIG. 11B) and the source electrodes S1 and the drain electrodes D1 of the phototransistors M1 (as shown in FIG. 11A).

S3013: over the substrate 21 having the aforementioned structures, forming a first insulating layer 14a through a plasma enhanced chemical vapor deposition (PECVD) process.

S3014: over the substrate having the first insulating layer 14a, forming a second active layer 13b of the switch transistors M2 as shown in FIG. 11B through one-time patterning process.

Herein, the second active layer 13b of the switch transistors M2 can have a substantially same composition as the first active layer 13a of the phototransistors M1.

S3015: over the substrate 21 having the aforementioned structures, forming a second metal electrode layer, and then perform a patterning process over the second metal electrode layer to thereby form the source electrodes S2 and the drain electrodes D2 of the switch transistors M2 as shown in FIG. 10B, and the gate electrodes G1 of the phototransistors M1.

S3016: over the substrate 21 having the aforementioned structures, forming an optical-electrical conversion layer 15 of the phototransistors M1 as shown in FIG. 10A through a one-time patterning process.

Specifically, the optical-electrical conversion layer can be fabricated by processes such as vapor deposition, sputtering, or spin coating, and the optical-electrical conversion layer can be further patterned through processes such as masking, exposure, development or etching, to ultimately form the optical-electrical conversion layer 15.

It should be noted that the optical-electrical conversion layer 15 can have a composition having, or partially having, a photovoltaic effect to lights with a wavelength ranging 300 nm-2000 nm in the spectrum.

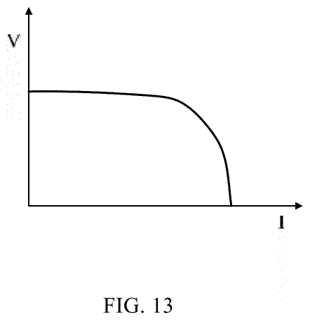

A photovoltaic characteristic curve according to some embodiment is illustrated in FIG. 13. By means of the photovoltaic characteristic curve, the relationship between the output voltage V and the output current I of the optical-electrical conversion layer 15 during the optical-electrical conversion process can be known.

S3017: over the substrate 21 having the aforementioned structures, forming the second insulating layer 14b.

S3018: over the substrate 21 having the aforementioned structures, forming a transparent conductive layer, and then perform a patterning process over the transparent conductive layer to thereby form the pixel electrodes 16 as shown in FIG. 11B and signal lead lines 17 as shown in FIG. 11A.

As shown in FIG. 10A, each signal lead line 17 is coupled to a first electrode (e.g. a source electrode S1) of a phototransistor M1 through a via 18a disposed through the second insulating layer 14b and the first insulating layer 14a to thereby allow the first electrode of the phototransistor M1 to be electrically connected to a corresponding read line RL as shown in FIG. 5A, or is coupled to a second electrode (e.g. a drain electrode D1) of the phototransistors M1 through a via 18b disposed through the second insulating layer 14b and the first insulating layer 14a to thereby allow the second electrode of the phototransistor M1 to be electrically connected to an anode

1. A display panel, comprising:
a plurality of sub-pixels; and
an image capturing assembly, comprising a plurality of photoelectric converters and an image integrator electrically coupled to each of the plurality of photoelectric converters;
wherein:
at least one of the plurality of sub-pixels contains one of the plurality of photoelectric converters to thereby each form a first sub-pixel;
each of the plurality of photoelectric converters is configured to convert an optical signal from an outside light reaching thereonto into an electrical signal; and
the image integrator is configured to receive the electrical signal from the each of the plurality of photoelectric converters to thereby build an image based thereupon.

2. The display panel of claim 1, further comprising:
an array substrate, comprising a substrate;
a color filter layer, disposed over the substrate and comprising a plurality of color blocks, each of a primary color and corresponding to one of the plurality of sub-pixels;
wherein:
the plurality of photoelectric converters are each disposed between the substrate and the color filter layer; and
each of the plurality of photoelectric converters is configured to convert an optical signal from an outside light entering through one of the plurality of color blocks into an electrical signal.

3. The display panel of claim 2, further comprising an optical functional layer, disposed over a surface of the color filter layer that is opposing to the substrate, wherein:
the optical functional layer is arranged such that an orthographic projection thereof on the substrate covers an orthographic projection of each first sub-pixel on the substrate, and is configured to increase a quantity of the light reaching one of the plurality of photoelectric converters in the each first sub-pixel.

4. The display panel of claim 3, wherein the optical functional layer comprises a plurality of first-level microlenses, arranged in a matrix, wherein:
each of the plurality of first-level microlenses has a surface that is convex in a direction away from the substrate.

5. The display panel of claim 4, wherein the optical functional layer further comprises a plurality of second-level microlenses, disposed over a surface of the plurality of first-level microlenses opposing to the substrate, wherein:
each of the plurality of second-level microlenses has a surface that is convex in a direction away from the substrate.

6. The display panel of claim 1, further comprising a plurality of read lines, a plurality of scan lines, and a plurality of common electrode lines, wherein:
each of the plurality of photoelectric converters is electrically coupled to one of the plurality of read lines, one of the plurality of scan lines, and one of the plurality of common electrode lines, and is configured to convert the optical signal into the electrical signal under control of the one of the plurality of scan lines and the one of the plurality of common electrode lines, and then to output the electric signal to the one of the plurality of read lines; and
the image integrator is electrically coupled to each of the plurality of read lines, and is configured to receive the electric signal transmitted through the each of the plurality of read lines.

7. The display panel of claim 6, wherein:
each of the plurality of read lines also serves as a data line; and
each of the plurality of scan lines also serves as a gate line.

8. The display panel of claim 6, further comprising a driving circuit, a source electrode driver, and a gate electrode driver, wherein:
the image integrator is further configured to integrate the electrical signal from the each of the plurality of photoelectric converters into an image data based on a location of a first sub-pixel corresponding thereto and a color block corresponding thereto; and
the driving circuit is electrically coupled to the source electrode driver, the image integrator and the gate electrode driver, and is configured to receive the image data outputted from the image integrator, and then to output control signals to the source electrode driver and the gate electrode driver to thereby display an image based on the image data.

9. The display panel of claim 6, wherein each of the plurality of photoelectric converters comprises a phototransistor and a commutation diode, wherein:
a gate electrode of the phototransistor is electrically coupled to one of the plurality of scan lines;
a first electrode of the phototransistor is electrically coupled to one of the plurality of read lines;
a second electrode of the phototransistor is electrically coupled to an anode of the commutation diode; and
a cathode of the commutation diode is electrically coupled to one of the plurality of common electrode lines.

10. The display panel of claim 6, wherein the image integrator comprises an electron-to-voltage converter, an amplifier, an analog-to-digital converter, a data processor, and a plurality of shift registers, wherein:
each of the plurality of shift registers is arranged within a first sub-pixel, is electrically coupled to one photoelectric converter corresponding to the first sub-pixel, and is configured to cache the electrical signal from the one photoelectric converter;
the electron-to-voltage converter is electrically coupled to each of the plurality of shift registers, and is configured to convert the electrical signal cached therein into a voltage signal in a line-by-line manner;
the amplifier is electrically coupled to the electron-to-voltage converter, and is configured to amplify the voltage signal from the electron-to-voltage converter to thereby obtain an amplified voltage signal;
the analog-to-digital converter is electrically coupled to the amplifier, and is configured to convert the amplified voltage signal from the amplifier from an analog format into a digital signal; and
the data processor is electrically coupled to the analog-to-digital converter, and is configured to integrate the digital signal received from the analog-to-digital converter, and to form a planar dot array based on a location of each first sub-pixel and each color block corresponding to the each first sub-pixel to thereby generate the image data.

11. The display panel of claim 2, wherein:
each of the plurality of sub-pixels includes a switch transistor; and
each of the plurality of photoelectric converters comprises a phototransistor;
wherein:
the switch transistor and the phototransistor are configured to share at least one film layer.

12. (canceled)

13. The display panel of claim 11, wherein the phototransistor comprises:
a first active layer, disposed over the substrate;
a source electrode and a drain electrode, disposed over the substrate and arranged to juxtapose the first active layer;
a first insulating layer, arranged to cover, and configured to provide insulation to, the first active layer, the source electrode and the drain electrode;
a gate electrode, disposed over the first insulating layer;
an optical-electrical conversion layer, disposed over the gate electrode;
a second insulating layer, arranged to cover, and configured to provide insulation to, the gate electrode and the optical-electrical conversion layer; and
two signal lead lines, respectively coupled electrically to the source electrode through a first via arranged through the second insulating layer and the first insulating layer, and to the drain electrode through a second via arranged through the second insulating layer and the first insulating layer.

14. The display panel of claim 13, wherein at least one of the source electrode and the drain electrode, the first insulating layer, the gate electrode, the second insulating layer, or any of the two signal lead lines of the phototransistor has a substantially same composition of, and is at a substantially same layer as, a film layer of the switch transistor.

15. The display panel of claim 14, wherein:
the source electrode and the drain electrode of the phototransistor have a substantially same composition of, and are at a substantially same layer as, a gate electrode of the switch transistor;
the first insulating layer of the phototransistor has a substantially same composition of, and is at a substantially same layer as, a first insulating layer of the switch transistor;
the gate electrode of the phototransistor has a substantially same composition of, and is at a substantially same layer as, a source electrode and a drain electrode of the switch transistor;
the second insulating layer of the phototransistor has a substantially same composition of, and is at a substantially same layer as, a second insulating layer of the switch transistor; and
the two signal lead lines of the phototransistor have a substantially same composition of, and are at a substantially same layer as, a pixel electrode of the switch transistor.

16. The display panel of claim 15, wherein the second insulating layer of the switch transistor is provided with a third via, wherein:
the pixel electrode of the switch transistor is electrically coupled to the drain electrode of the switch transistor through the third via.

17. (canceled)

18. (canceled)

19. The display panel of claim 1, wherein each first sub-pixel is in an image capturing sub-region arranged in a non-display region of the display panel.

20. (canceled)

21. The display panel of claim 1, wherein each first sub-pixel is in a display region of the display panel.

22. The display panel of claim 21, wherein each first sub-pixel is in a dummy display sub-region of the display region that is covered by a bezel disposed over a side thereof opposing to the substrate, wherein:
the bezel is provided with a light-transmitting hole, arranged to allow a light from an environment of the display panel to transmit therethrough and reach a photoelectric converter corresponding to the each first sub-pixel.

23. The display panel of claim 21, wherein each first sub-pixel is uniformly distributed at the display region.

24. A display apparatus, comprising a display panel according to claim 1.
